(19) United States
(12) Patent Application Publication
(10) Pub. No.: US 2024/0385530 A1
(43) Pub. Date: Nov. 21, 2024

(54) ETCHING SYSTEMS, MODELS, AND MANUFACTURING PROCESSES

(71) Applicant: ASML NETHERLANDS B.V., Veldhoven (NL)

(72) Inventors: Jiao HUANG, Shenzhen (CN); Jinze Wang, Shenzhen (CN); Yan YAN, Shenzhen (CN); Yongfa FAN, Cupertino, CA (US); Liang Liu, Shenzhen (CN); Mu FENG, San Jose, CA (US)

(73) Assignee: ASML NETHERLANDS B.V., Veldhoven (NL)

(21) Appl. No.: 18/565,494

(22) PCT Filed: May 29, 2022
(86) PCT No.: PCT/EP2022/064507

§ 371 Date: Nov. 29, 2023

(30) Foreign Application Priority Data
Jun. 23, 2021 (WO) PCT/CN2021/101783

(51) Int. Cl. G03F 7/00

(52) U.S. Cl. CPC G03F 7/705; G03F 7/70508; G03F 7/70625

(57) ABSTRACT

Etch bias is determined based on a curvature of a contour in a substrate pattern. The etch bias is configured to be used to enhance an accuracy of a semiconductor patterning process relative to prior patterning processes. In some embodiments, a representation of the substrate pattern is received, which includes the contour in the substrate pattern. The curvature of the contour of the substrate pattern is determined and inputted to a simulation model. The simulation model includes a correlation between etch biases and curvatures of contours. The etch bias for the contour in the substrate pattern is outputted by the simulation model based on the curvature.

### CROSS-REFERENCE TO RELATED APPLICATIONS

This application claims priority of International application PCT/CN2021/101783 which was filed on 23 Jun. 2021 and which is incorporated herein in its entirety by reference.

### TECHNICAL FIELD

The present disclosure relates generally to etching simulations associated with computational lithography.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference. Prior to transferring the pattern from the patterning device to the substrate, the substrate may

undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore”s law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

Etch effects are often taken into consideration during OPC and/or other processes (e.g., for patterning process optimization and/or other purposes). A simulation model can be used to predict etch effects such as etch bias, for example. Prior simulation models include different terms configured to simulate various kinds of etch effects. For example, prior simulation models include terms configured to simulate influence from nearby features in a wafer (substrate) pattern on etch bias at a local etch position. Also, density maps and/or other tools may be used to simulate long range wafer pattern geometry effects on the (local) etch bias. However, prior simulation models do not account for the influence of in-plane curvatures of contours in a wafer pattern on the etch bias.

Thus, according to an embodiment, there is provided a non-transitory computer readable medium having instructions thereon. The instructions, when executed by a computer, cause the computer to receive a representation of a contour of a substrate (e.g., wafer) pattern, determine a curvature of the contour, and use a simulation model to determine an etch effect. The simulation model comprises a correlation between etch biases and curvatures of contours. In some embodiments, the etch effect is an etch bias, and the instructions cause the computer to output, based on the simulation model, an etch bias for the substrate pattern based on the curvature.

In some embodiments, the curvature is determined based on (1) a slope of the contour; and (2) a maximum or a minimum in the contour.

In some embodiments, the curvature is determined based on first and second derivatives of the contour.

In some embodiments, the curvature is determined by a ratio between the second derivative and the first derivative.

In some embodiments, the simulation model comprises a multi-dimensional algorithm. In some embodiments, the multi-dimensional algorithm comprises one or more non-linear, linear, or quadratic functions representative of parameters of an etching process.

In some embodiments, the simulation model comprises a physical etch model or a semi-physical etch model.

In some embodiments, the simulation model is an etch model. In some embodiments, the etch model comprises a multi-dimensional algorithm including a curvature term configured to correlate the curvature with the etch bias.

In some embodiments, the contour is obtained from a representation of the substrate pattern from an after development inspection for the substrate pattern.

In some embodiments, the contour is obtained from a resist model and/or an optical model.

In some embodiments, the etch effect is an etch bias, and the etch bias is configured to be provided to a cost function to facilitate determination of costs associated with individual patterning process variables.

According to another embodiment, there is provided a method for determining an etch effect for a substrate pattern. The method comprises: receiving a representation of a contour of the substrate pattern; determining a curvature of the contour; and using a simulation model to determine the etch effect for the substrate pattern based on the curvature. The simulation model comprises a correlation between etch biases and curvatures of contours. In some embodiments, the etch effect is an etch bias.

In some embodiments, the curvature is determined based on (1) a slope of the contour; and (2) a maximum or a minimum in the contour.

In some embodiments, the curvature is determined based on first and second derivatives of the contour.

In some embodiments, the curvature is determined by a ratio between the second derivative and the first derivative.

In some embodiments, the simulation model comprises a multi-dimensional algorithm, and wherein the multi-dimensional algorithm comprises one or more non-linear, linear, or quadratic functions representative of parameters of an etching process.

In some embodiments, the simulation model comprises a physical etch model or a semi-physical etch model. In some embodiments, the simulation model is an etch model, and the etch model comprises a multi-dimensional algorithm including a curvature term configured to correlate the curvature with the etch bias.

In some embodiments, the contour is obtained from a representation of the substrate pattern from an after development inspection for the substrate pattern.

In some embodiments, the contour is obtained from a resist model and/or an optical model.

In some embodiments, the etch effect is an etch bias, and the etch bias is configured to be provided to a cost function to facilitate determination of costs associated with individual patterning process variables.

According to another embodiment, there is provided a system for determining an etch effect for a substrate pattern. The system comprises one or more hardware processors configured by machine readable instructions to: receive a representation of a contour of the substrate pattern; determine a curvature of the contour; and use a simulation model to determine the etch effect for the substrate pattern based on the curvature. The simulation model comprises a correlation between etch biases and curvatures of contours. In some embodiments, the etch effect is an etch bias.

In some embodiments, the curvature is determined based on (1) a slope of the contour; and (2) a maximum or a minimum in the contour.

In some embodiments, the curvature is determined based on first and second derivatives of the contour.

In some embodiments, the curvature is determined by a ratio between the second derivative and the first derivative.

In some embodiments, the simulation model comprises a multi-dimensional algorithm, and wherein the multi-dimensional algorithm comprises one or more non-linear, linear, or quadratic functions representative of parameters of an etching process.

In some embodiments, the simulation model comprises a physical etch model or a semi-physical etch model. In some embodiments, the simulation model is an etch model, and the etch model comprises a multi-dimensional algorithm including a curvature term configured to correlate the curvature with the etch bias.

In some embodiments, the contour is obtained from a representation of the substrate pattern from an after development inspection for the substrate pattern.

In some embodiments, the contour is obtained from a resist model and/or an optical model.

In some embodiments, the etch effect is an etch bias, and the etch bias is configured to be provided to a cost function to facilitate determination of costs associated with individual patterning process variables.

According to another embodiment, there is provided a non-transitory computer readable medium having instructions thereon. The instructions, when executed by a computer, cause the computer to execute a simulation model for determining an etch bias for a pattern on a substrate. The etch bias is determined based on a curvature of a contour in the pattern. The etch bias is configured to be used to enhance an accuracy of a patterning process relative to prior patterning processes. The instructions cause operations comprising: receiving a representation of the pattern, where the representation comprises the contour in the pattern; determining the curvature of the contour of the pattern; inputting the curvature to the simulation model, where the simulation model comprises a correlation between etch biases and curvatures of contours; and outputting, based on the simulation model, the etch bias for the contour in the pattern. The etch bias from the simulation model is configured to be used in a cost function to facilitate determination of costs associated with individual patterning process variables. The costs associated with individual patterning variables are configured to be used to facilitate an optimization of the patterning process.

In some embodiments, the simulation model is an etch model.

In some embodiments, the representation of the pattern comprises (1) inspection results from an after development inspection for the pattern; or (2) a model of the contour in the pattern.

In some embodiments, the representation of the pattern comprises the inspection results from the after development inspection for the pattern, and the inspection results from the after development inspection for the pattern are obtained from a scanning electron microscope or an optical metrology tool.

In some embodiments, the curvature is determined based on (1) a slope of the contour in the pattern; and (2) a maximum or a minimum in the contour in the pattern.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 illustrates a present method, according to an embodiment.

FIG. 4 illustrates how a present simulation model can be used to predict after etch pattern feature contours based on etch effects such as etch bias, according to an embodiment.

FIG. 5 illustrates determination of a curvature of a contour in a substrate (e.g., wafer) pattern, according to an embodiment.

FIG. 6 illustrates an example quantification of the improvement provided by the present systems, models, and/or manufacturing processes relative to prior systems, models, and/or manufacturing processes, according to an embodiment.

FIG. 7 is a block diagram of an example computer system, according to an embodiment.

FIG. 8 is a schematic diagram of a lithographic projection apparatus, according to an embodiment.

FIG. 9 is a schematic diagram of another lithographic projection apparatus, according to an embodiment.

FIG. 10 is a detailed view of a lithographic projection apparatus, according to an embodiment.

FIG. 11 is a detailed view of the source collector module of the lithographic projection apparatus, according to an embodiment.

### DETAILED DESCRIPTION

As described above, etch effects are often taken into consideration during OPC and/or other processes (e.g., for patterning process optimization and/or other purposes). A simulation model can be used to predict after etch pattern feature contours based on etch effects such as etch bias, for example. Etch bias may be thought of as the change in a given substrate pattern feature dimension between an after development inspection (ADI) and an after etch inspection (AEI). Typically, a simulation model such as an effective etch bias (EEB) model simulates and/or otherwise determines an etch bias map for a wafer pattern based on dimensional differences in various pattern features between an ADI and an AEI. The etch bias map is used to determine after etch contours of pattern features.

Prior simulation models include different terms configured to simulate various kinds of etch effects, including etch bias. For example, prior simulation models include terms configured to simulate influence from nearby features in a substrate (e.g., wafer) pattern on etch bias at a local etch position. Also, density maps and/or other tools may be used to simulate long range wafer pattern geometry effects on the (local) etch bias. However, prior simulation models do not account for the influence of in-plane curvatures of contours in a wafer pattern on etch bias.

Advantageously, the present disclosure describes systems, models, and manufacturing processes (methods) for determining an etch effect for a pattern on a substrate (e.g., wafer) based on curvatures of contours in the pattern. For example, the etch effect may be represented by etch bias or etch profile or the like. The determined etch bias is configured to be used to enhance an accuracy of after etch contour determinations, and in turn enhance an overall accuracy of a patterning process relative to prior patterning processes. As described herein, a representation of the pattern is received, which includes a given contour in the pattern. The curvature of the contour of the pattern is determined and inputted to a simulation model. The simulation model comprises a correlation between etch biases and curvatures of contours. Etch bias for the contour in the pattern is outputted by the simulation model. Among other possible uses, the etch bias from the simulation model may be used to determine after etch feature contours, used in a cost function to facilitate determination of costs associated with individual patterning process variables, and/or used for other purposes. The after etch feature contours and/or the costs associated with individual patterning variables may be used to facilitate an optimization of a patterning process, for example.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the (e.g., semiconductor) patterning device, and/or optical components for shaping, adjusting and/or projecting the radiation after the radiation passes the patterning device. The projection optics generally exclude the source and the patterning device.

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model”, “process model”, “electronic model”, and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), and/or other models.

As used herein, the term “calibrating” means to modify (e.g., improve or tune) and/or validate something, such as a model.

A patterning system may be a system comprising any or all of the components described above, plus other components configured to performing any or all of the operations associated with these components. A patterning system may include a lithographic projection apparatus, a scanner, systems configured to apply and/or remove resist, etching systems, and/or other systems, for example.

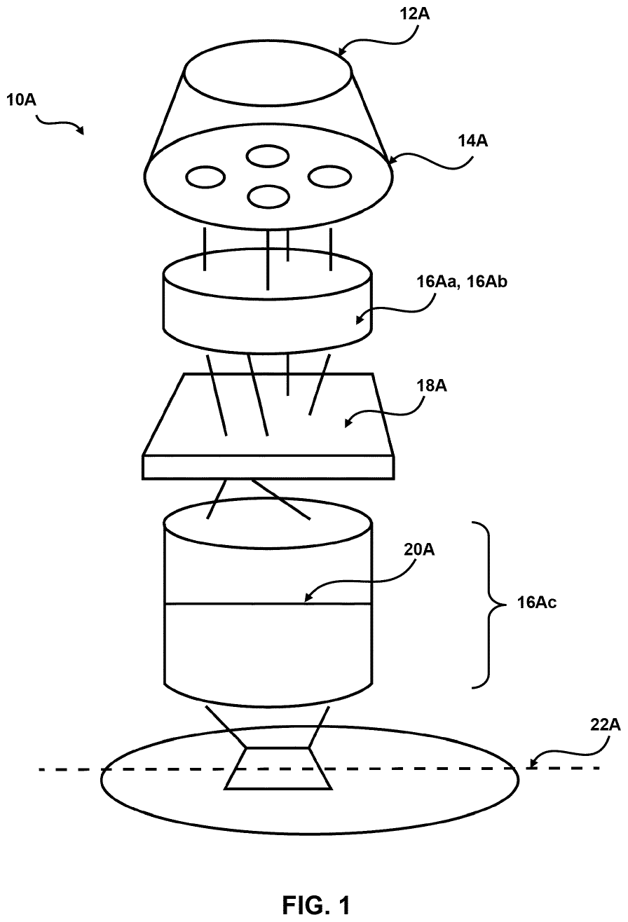

As an introduction, FIG. 1 illustrates a diagram of various subsystems of an example lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, for example, define the partial coherence (denoted as sigma) and which may include optics components 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

It may be desirable to use one or more tools to produce results that, for example, can be used to design, control, monitor, etc. the patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components and/or processes can be described by various functional modules and/or models. In some embodiments, one or more electronic (e.g., mathematical, parameterized, etc.) models may be provided that describe one or more steps and/or apparatuses of the patterning process (e.g., etching). In some embodiments, a simulation of the patterning process can be performed using one or more electronic models to simulate how the patterning process forms a patterned substrate using a pattern provided by a patterning device.

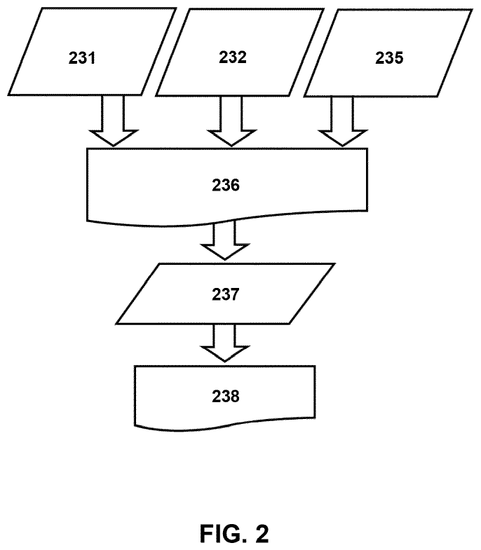

An exemplary flow chart for simulating lithography in a lithographic projection apparatus is illustrated in FIG. 2. An illumination model 231 represents optical characteristics (including radiation intensity distribution and/or phase distribution) of the illumination. A projection optics model 232 represents optical characteristics (including changes to the radiation intensity distribution and/or the phase distribution caused by the projection optics) of the projection optics. A design layout model 235 represents optical characteristics (including changes to the radiation intensity distribution and/or the phase distribution caused by a given design layout) of a design layout, which is the representation of an arrangement of features on or formed by a patterning device. An aerial image 236 can be simulated using the illumination model 231, the projection optics model 232, and the design layout model 235. A resist image 238 can be simulated from the aerial image 236 using a resist model 237. Simulation of lithography can, for example, predict contours and/or CDs in the resist image.

More specifically, illumination model 231 can represent the optical characteristics of the illumination that include, but are not limited to, NA-sigma (σ) settings as well as any particular illumination shape (e.g. off-axis illumination such as annular, quadrupole, dipole, etc.). The projection optics model 232 can represent the optical characteristics of the of the projection optics, including, for example, aberration, distortion, a refractive index, a physical size or dimension, etc. The design layout model 235 can also represent one or more physical properties of a physical patterning device, as described, for example, in U.S. Pat. No. 7,587,704, which is incorporated by reference in its entirety. Optical properties associated with the lithographic projection apparatus (e.g., properties of the illumination, the patterning device, and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 235).

The resist model 237 can be used to calculate the resist image from the aerial image, an example of which can be found in U.S. Pat. No. 8,200,468, which is hereby incorporated by reference in its entirety. The resist model is typically related to properties of the resist layer (e.g., effects of chemical processes which occur during exposure, post-exposure bake and/or development).

One of the objectives of the full simulation is to accurately predict, for example, edge placements, aerial image intensity slopes and/or CDs, which can then be compared against an intended design. The intended design is generally defined as a pre-OPC design layout which can be provided in a standardized digital file format such as GDS, GDSII, OASIS, or other file formats.

From the design layout, one or more portions may be identified, which are referred to as “clips.” In an embodiment, a set of clips is extracted, which represents the complicated patterns in the design layout (typically about 50 to 1000 clips, although any number of clips may be used). As will be appreciated by those skilled in the art, these patterns or clips represent small portions (e.g., circuits, cells, etc.) of the design and especially the clips represent small portions for which particular attention and/or verification is needed. In other words, clips may be the portions of the design layout or may be similar or have a similar behavior of portions of the design layout where critical features are identified either by experience (including clips provided by a customer), by trial and error, or by running a full-chip simulation. Clips often contain one or more test patterns or gauge patterns. An initial larger set of clips may be provided a priori by a customer based on known critical feature areas in a design layout which require particular image optimization. Alternatively, in another embodiment, the initial larger set of clips may be extracted from the entire design layout by using an automated (such as, machine vision) or manual algorithm that identifies the critical feature areas.

For example, the simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be generally referred to as, respectively, mask optimization, source optimization, and projection optimization. Such optimization can be performed on their own, or combined in different combinations. One such example is source-mask optimization (SMO), which involves the configuring of one or more features of the patterning device pattern together with one or more features of the illumination. The optimization techniques may focus on one or more of the clips. The optimizations may use the machine learning model described herein to predict values of various parameters (including images, etc.).

Similar modelling techniques may be applied for optimizing an etching process, for example, and/or other processes. In some embodiments, illumination model 231, projection optics model 232, design layout model 235, resist model 237, and/or other models may be used in conjunction with an etch model, for example. For example, output from an after development inspection (ADI) model (e.g., included as some and/or all of design layout model 235, resist model 237, and/or other models) may be used to determine an ADI contour, which may be provided to an effective etch bias (EEB) model to generate a predicted after etch inspection (AEI) contour.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as one or more etching parameters, dose and focus, etc., for example.

In an etching system, as an example, a cost function (CF) may be expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} )$$

where (z₁, z₂, . . . , zₙ) are N design variables or values thereof, and ƒₚ(z₁, z₂, . . . , zₙ) can be a function of the design variables (z₁, z₂, . . . , zₙ) such as a difference between an actual value and an intended value of a characteristic for a set of values of the design variables of (z₁, z₂, . . . , zₙ). In some embodiments, wₚ is a weight constant associated with ƒₚ(z₁, z₂, . . . , zₙ). For example, the characteristic may be a position of an edge of a pattern, measured at a given point on the edge. Different ƒₚ(z₁, z₂, . . . , zₙ) may have different weight wₚ. For example, if a particular edge has a narrow range of permitted positions, the weight wₚ for the ƒₚ(z₁, z₂, . . . , zₙ) representing the difference between the actual position and the intended position of the edge may be given a higher value. ƒₚ(z₁, z₂, . . . , zₙ) can also be a function of an interlayer characteristic, which is in turn a function of the design variables (z₁, z₂, . . . , zₙ). Of course, CF(z₁, z₂, . . . , zₙ) is not limited to the form in the equation above and CF(z₁, z₂, . . . , zₙ) can be in any other suitable form.

The cost function may represent any one or more suitable characteristics of the etching system, etching process, lithographic apparatus, lithography process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of a resist image. For example, ƒₚ(z₁, z₂, . . . , zₙ) can be simply a distance between a point in the resist image to an intended position of that point (i.e., edge placement error EPEₚ(z₁, z₂, . . . , zₙ) after etching, for example, and/or some other process. The parameters (e.g., design variables) can include any adjustable parameter such as an adjustable parameter of the etching system, the source, the patterning device, the projection optics, dose, focus, etc.

The parameters (e.g., design variables) may have constraints, which can be expressed as (z₁, z₂, . . . , zₙ)∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity.

In some embodiments, illumination model 231, projection optics model 232, design layout model 235, resist model 237, an etch model, and/or other models associated with and/or included in an integrated circuit manufacturing process may be an empirical and/or other simulation model that performs at least some of the operations of the method described herein. The empirical model may predict outputs based on correlations between various inputs (e.g., one or more characteristics of a pattern such as curvature, one or more characteristics of the patterning device, one or more characteristics of the illumination used in the lithographic process such as the wavelength, etc.).

As an example, the empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training information. The training information may include a set of training samples. Each sample may be a pair comprising an input object (typically a vector, which may be called a feature vector) and a desired output value (also called the supervisory signal). A training algorithm analyzes the training information and adjusts the behavior of the neural network by adjusting the parameters (e.g., weights of one or more layers) of the neural network based on the training information. For example, given a set of N training samples of the form {(x₁, y₁), (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a simulated aerial image, a wafer design, a clip, etc.). The vector space associated with these vectors is often called the feature space. After training, the neural network may be used for making predictions using new samples.

As another example, the empirical (simulation) model may comprise one or more algorithms. The one or more algorithms may be and/or include mathematical equations, plots, charts, and/or other tools and model components. For example, in some embodiments, the present systems and methods include (or use) an empirical simulation model that comprises one or more multi-dimensional algorithms. The one or more multi-dimensional algorithms comprise one or more non-linear, linear, or quadratic functions representative of the physical parameters of an etching process. In some embodiments, the one or more multi-dimensional algorithms comprise a curvature term configured to, alone or in combination with other algorithm terms, correlate curvatures with etch biases. In some embodiments, the empirical simulation model comprising the one or more algorithms may be considered a physical etch model. The physical etch model can be and/or include an effective etch bias (EEB) model, a resist model (e.g., resist model 237) in combination with an etch bias model, and/or other models. This is further described below.

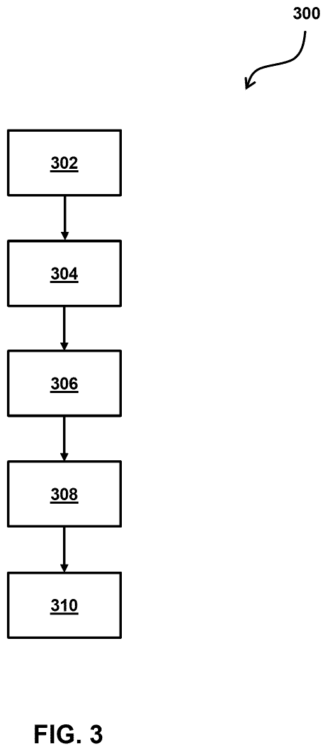

FIG. 3 illustrates an exemplary method 300 according to an embodiment of the present disclosure. In some embodiments, method 300 comprises receiving 302 a representation of a contour in a substrate pattern, determining 304 a curvature of the contour, inputting 306 the curvature to the simulation model, and outputting 308 an etch bias for the substrate pattern based on the curvature. In some embodiments, method 300 includes using 310 the etch bias to predict after etch feature contours in a substrate (wafer) pattern, in a cost function to facilitate determination of costs associated with individual patterning process variables, and/or in other operations. It will be appreciated that the present disclosure is not limited to any specific method or algorithm for determining or obtaining contours.

In some embodiments, a non-transitory computer readable medium stores instructions which, when executed by a computer, cause the computer to execute one or more of operations 302-310, and/or other operations. The operations of method 300 are intended to be illustrative. In some embodiments, method 300 may be accomplished with one or more additional operations not described, and/or without one or more of the operations discussed. For example, operation 310 and/or other operations may be optional. Additionally, the order in which the operations of method 300 are illustrated in FIG. 3 and described herein is not intended to be limiting.

At operation 302, a representation of a contour in a substrate pattern is received. The representation comprises the contour in the pattern and/or other information. For example, the representation may include information describing the geometrical shape of the contour in the pattern and/or information related to the geometrical shape. The geometrical shape of the contour in the pattern may be a two dimensional geometrical shape, for example. The received representation includes data that describes the characteristics of the contour (e.g., such as X-Y dimensional data points, a mathematical equation that describes the geometrical shape, etc.), processing parameters associated with the contour, and/or other data. In some embodiments, the representation of the pattern comprises inspection results from an after development inspection (ADI) for the pattern, a model of the contour in the pattern, and/or other information. The inspection results from the after development inspection for the pattern may be obtained from a scanning electron microscope, an optical metrology tool, and/or other sources. In some embodiments, the contour is obtained from a resist model (e.g., as shown in FIG. 2 and described above), an optical model (e.g., as shown in FIG. 2 and described above), and/or other modelling sources.

The representation may be received electronically from one or more other portions of the present system (e.g., from a different processor, or from a different portion of a single processor), from a remote computing system not associated with a present system, and/or from other sources. The representation may be received wirelessly and/or via wires, via a portable storage medium, and/or from other sources. The representation may be uploaded and/or downloaded from another source, such as cloud storage for example, and/or received in other ways.

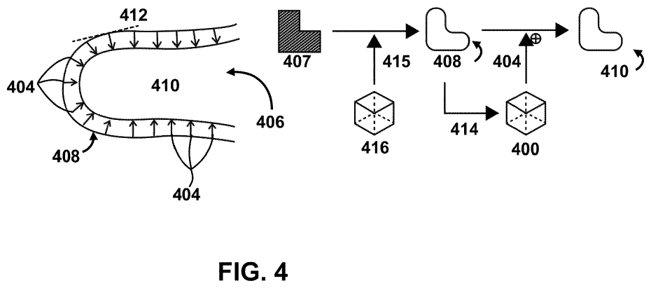

By way of a non-limiting example, FIG. 4 illustrates how a simulation model 400 can be used to predict after etch pattern contours based on etch effects such as etch bias 404, for example. As shown in FIG. 4, etch bias describes the dimensional change in a given substrate pattern feature 406 between an after development inspection (ADI) contour 408 and an after etch inspection (AEI) contour 410 at a given location. (Pattern feature 406 may be generated via a corresponding portion of a mask 407.) A bias direction 412 can be perpendicular to ADI contour 408, but the present disclosure is not limited thereto. Simulation model 400 simulates and/or otherwise determines etch bias 404 for a wafer pattern based on ADI contour 408 (and/or other information) for generation of AEI contour 410. More generally, the etch bias from model 400 can be used to determine after etch contours of various pattern features (e.g., pattern feature 406 and/or other pattern feature not shown in FIG. 4).

FIG. 4 also illustrates receiving 414 a representation of a contour (e.g., ADI contour 408 in this example) in a substrate pattern. As described above, the representation of the contour (e.g., ADI contour 408) may be derived from inspection results from an after development inspection (ADI) for the pattern, a model of the contour in the pattern, and/or any other suitable information. In the example shown in FIG. 4, contour 408 is obtained 415 from a resist model and/or an optical model 416.

Returning to FIG. 3, at operation 304, a curvature of the contour in the substrate pattern is determined. The curvature is an in-plane curvature (e.g., for a two dimensional contour as shown in FIG. 4). The curvature corresponds to nearby in-plane bending effects for localized etch positions. Curvature can be an indication of the activation energy at a given localized etch position, which influences etch effects. The present disclosure is not limited to any specific method, process, operation or algorithm of determining the curvature. The curvature can be determined based on a slope of the contour in the pattern, a maximum or a minimum in the contour in the pattern, and/or other information. The slope, the maximum, and/or the minimum may be determined based on first and or second derivatives of the contour, for example. In some embodiments, the curvature is determined by a ratio between the second derivative and the first derivative and/or other mathematical operations. It should be noted that although the present disclosure describes determining a single curvature, curvature may be determined at one or more locations along the contour (and inputted to the simulation model as described below).

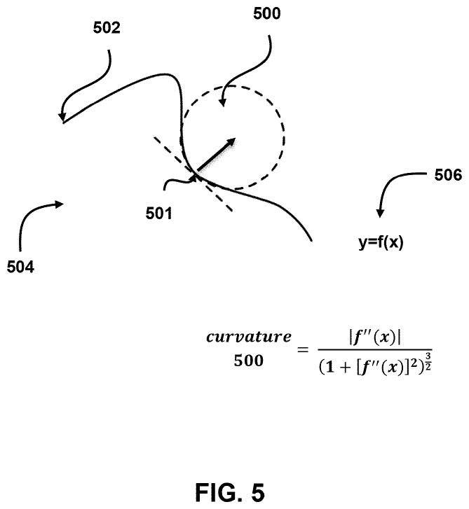

By way of a non-limiting example, FIG. 5 illustrates determination of a curvature 500 at a given location 501 in a contour 502 in a substrate (e.g., wafer) pattern 504. As shown in FIG. 5, curvature 500 is an in-plane curvature (e.g., for a two dimensional contour 502). In some embodiments, curvature 500 is determined based on a slope (e.g., an inclined or declined portion) of contour 502 in pattern 504, a maximum or a minimum (e.g., an inflection point) in contour 502 in pattern 504, and/or other information. The slope, the maximum, and/or the minimum may be determined based on first and or second derivatives of contour 502, for example. Curvature 500 is also determined by a ratio between the second derivative and the first derivative. For example, contour 502 can be described by a function 506 y=f(x). Using function 506, curvature 500 can be determined based on the following equation:

$$curvature = \frac{\vert {f}^{″} ( x ) \vert}{{( 1 + {[ {f}^{′} ( x ) ]}^{2} )}^{\frac{3}{2}}}$$

where ƒ′is the first derivative of function 506 and ƒ″is the second derivative. In the equation shown above, the absolute value of the second derivative of function 506 is divided by (e.g., ratioed with) the first derivative of function 506 (modified by various constants and exponents) to determine curvature 500. In some embodiments, it may be possible to determine curvature using other combinations of the first derivative, the second derivative, and/or various other constants and equation terms. These embodiments should be considered to be within the spirit and scope of the present invention.

Returning to FIG. 3, at operation 306, the curvature is inputted to the simulation model. Inputting may include electronically sending, uploading, and/or otherwise providing the curvature to the simulation model. In some embodiments, the simulation model may be integrally programmed with the instructions that cause others of operations 302-310 (e.g., such that no “inputting” is required, and instead data simply flows directly to the simulation model). The simulation model is configured to predict the impact pattern contour curvatures may have on a local etch bias. The simulation model is configured to receive pattern contour curvatures and determine etch biases. In contrast to prior systems, the simulation model comprises an in plane curvature term that is not included in prior models. The simulation model comprises a correlation between etch biases and curvatures of contours. For example, the model is configured to correlate the in-plane curvature with nearby in-plane bending effects for localized etch positions.

The simulation model is a physical or semi-physical etch (or etch bias) model. The physical or semi-physical etch model describes the physical parameters of an etch process as governed by chemistry/physics/mathematics principals in algorithm (e.g., with different terms for different physical parameters) and/or other forms. The physical or semi-physical etch model is configured to determine AEI contours (e.g., see model 400 and contour 410 FIG. 4) based on ADI contours (e.g., contour 408 in FIG. 4 or contour 502 in FIG. 5). It has various terms corresponding to respective physical etch effects. The physical or semi-physical etch model can be and/or include an effective etch bias (EEB) model, a resist model in combination with an etch bias model, and/or other models. In some embodiments, the simulation model comprises a multi-dimensional algorithm (or more than one multi-dimensional algorithm). The multi-dimensional algorithm comprises one or more non-linear, linear, or quadratic functions representative of parameters of an etching process. The simulation model comprises a curvature term configured to correlate the curvature with the etch bias. The curvature term may be combined with one or more additional terms in the multi-dimensional algorithm to determine the etch bias, for example.

In some embodiments, the simulation model is a calibrated prediction model, for example. The simulation model is calibrated with curvature calibration data and corresponding etch bias calibration data. Calibration may include model generation, training, tuning, and/or other operations. Curvature calibration data and corresponding etch bias calibration data comprise known and/or otherwise previously determined data. The curvature and/or etch bias calibration data may be measured, simulated, and/or determined in other ways. In some embodiments, the calibration data is obtained by executing a full simulation model (e.g., where a full simulation model may include one or more of illumination model 231, projection optics model 232, design layout model 235, resist model 237, and/or other models).

In some embodiments, the simulation model is calibrated by providing the curvature calibration data to a base (simulation) model to obtain a prediction of the etch bias calibration data, and using the etch bias calibration data as feedback to update one or more configurations of the base model. For example, the one or more configurations of the simulation model may be updated based on a comparison between the etch bias calibration data and the prediction of the etch bias calibration data. The calibration data used for calibrating the simulation model may include pairs or sets of inputs (e.g., known curvatures) and corresponding known outputs (e.g., known corresponding etch biases. A calibrated simulation model can then be used to make predictions (e.g., on etch bias) based on new curvatures.

The present disclosure is not limited by any specific forms or algorithms of the simulation model. In some embodiments, the simulation model comprises the multi-dimensional algorithm described above. In some embodiments, calibrating the model comprises updating one or more configurations of the base model by tuning and/or otherwise adjusting one or more parameters of the algorithm. In some embodiments, tuning comprises adjusting one or more model parameters such that predicted etch bias data better matches, or better corresponds to, known etch bias data for corresponding curvatures. In some embodiments, tuning comprises training or re-training the model using additional calibration information comprising new and/or additional input/output calibration data pairs.

In some embodiments, the simulation model (e.g., the multi-dimensional algorithm) comprises one or more of a non-linear algorithm, a linear algorithm, a quadratic algorithm, or a combination thereof but can and/or include any suitable arbitrary mathematical function. For example, the function may have a power polynomial form, a piece-wise polynomial form, exponential forms, Gaussian forms, sigmoid forms, decision-tree type of forms, etc. These algorithms may include any number of parameters, weights, and/or other features, in any combination such that the function is configured to mathematically correlate curvatures with etch biases.

In some embodiments, the form of the algorithm (e.g., non-linear, linear, quadratic, etc.), the parameters of the algorithm, the weights in the algorithm, and/or other characteristics of the algorithm may be determined automatically based on the calibration described above, based on accuracy and runtime performance specifications provided by a user, based on manual entry and/or selection of information by a user through a user interface included in the present system, and/or by other methods. In some embodiments, the form of the algorithm (e.g., non-linear, linear, quadratic, etc.), the parameters of the algorithm, and/or other characteristics of the algorithm may change with individual layers of a substrate (e.g., as processing parameters and/or other conditions that might cause and/or affect etching change), and/or based on other information. For example, different models may be calibrated for different layers of a substrate produced during semiconductor device manufacturing etching operations.

At operation 308, an etch bias is outputted from the simulation model. The etch bias is for the determined contour in the pattern. The etch bias may be outputted electronically to one or more other portions of the present system (e.g., to a different processor), to a remote computing system not associated with a present system, and/or to other locations. The etch bias may be outputted wirelessly and/or via wires, via a portable storage medium, and/or with other components. The etch bias may be uploaded and/or downloaded to another source, such as cloud storage for example, and/or outputted in other ways.

At operation 310, the etch bias is used in a cost function to facilitate determination of costs associated with individual patterning process variables and/or metrics. The costs associated with individual patterning variables are configured to be used to facilitate an optimization of the patterning process. In some embodiments, costs associated with the individual patterning process variables are configured to be provided to an optimizer to facilitate (e.g. co-) optimization of an etching process, patterning systems (e.g., scanners), and/or other semiconductor manufacturing processes and/or systems. In general, an optimizer is a computer algorithm that finds the minimum of a given cost function. An optimizer may be a gradient based non-linear optimizer configured to co-determine multiple etching process variables, for example. An optimizer may be formed by one or more processors configured to balance different possible process variables (e.g., each within their own allowable ranges) against manufacturing capabilities or costs associated with different metrics (e.g., a critical dimension, a pattern placement error, an edge placement error, critical dimension asymmetry, a defect count associated with an etching process, and/or other metrics).

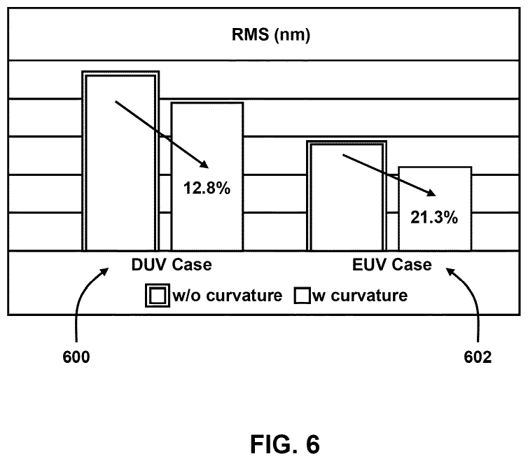

FIG. 6 illustrates an example quantification of the improvement provided by the present systems, models, and/or manufacturing processes relative to prior systems, models, and/or manufacturing processes. FIG. 6 illustrates how, for both DUV 600 and EUV 602 applications, there is a decrease in pattern RMS (root mean square-used as a measure of surface roughness) if the curvature is used to determine etch bias as described above. Experimental results showed a 12.8% decrease for DUV 600 applications, and a 21.3% decrease for EUV 602 applications.

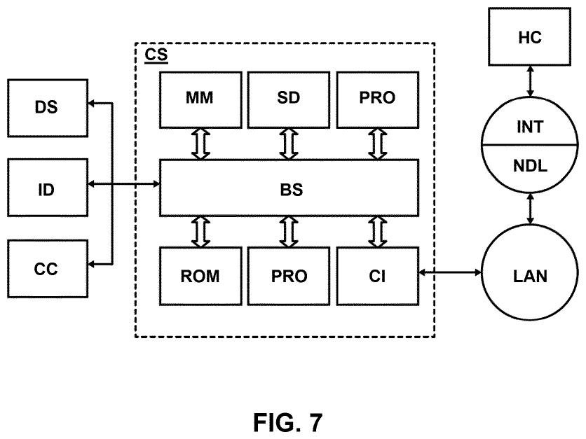

FIG. 7 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

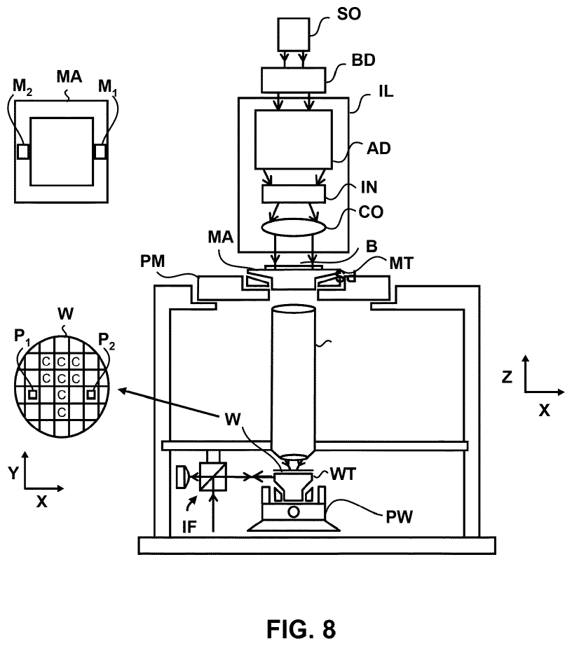

FIG. 8 is a schematic diagram of a lithographic projection apparatus, according to an embodiment. The lithographic projection apparatus can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer and/or inner radial extent (commonly referred to as o-outer and o-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept essentially stationary, and an entire patterning device image is projected in one operation (i.e., a single “flash”) onto a target portion C. Substrate table WT can be shifted in the x and/or y directions so that a different target portion C can be irradiated by beam B. In scan mode, essentially the same scenario applies, except that a given target portion C is not exposed in a single “flash.” Instead, patterning device table MT is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=1/4 or 1/5). In this manner, a relatively large target portion C can be exposed, without having to compromise on resolution.

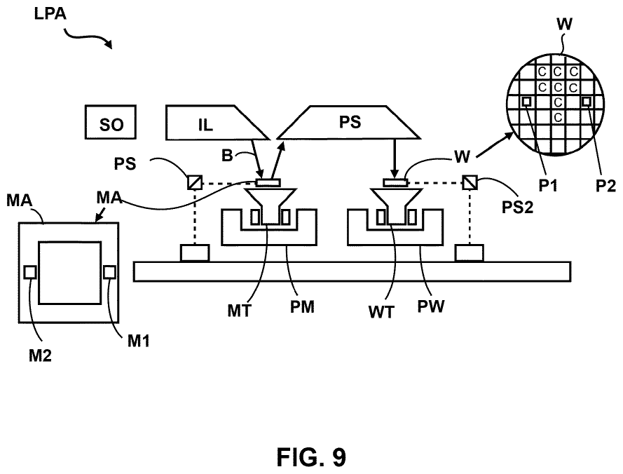

FIG. 9 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g. EUV radiation), support structure MT, substrate table WT, and projection system PS. Support structure (e.g. a patterning device table) MT can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 9), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g. patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de)magnification and image reversal characteristics of the projection system PS. In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

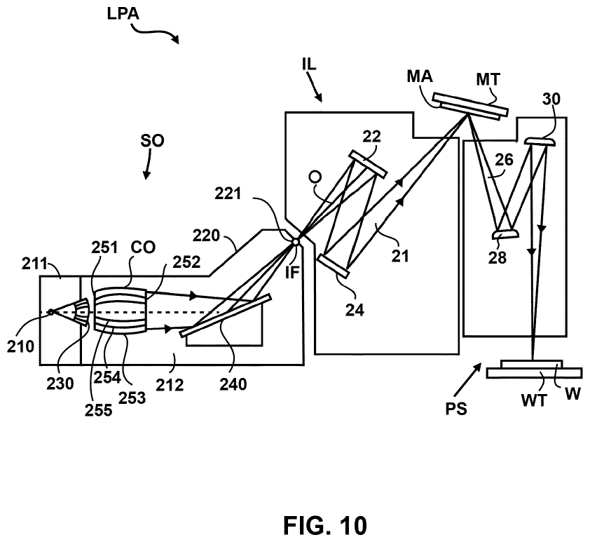

FIG. 10 is a detailed view of the lithographic projection apparatus shown in FIG. 9. As shown in FIG. 10, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 10.

Collector optic CO, as illustrated in FIG. 10, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

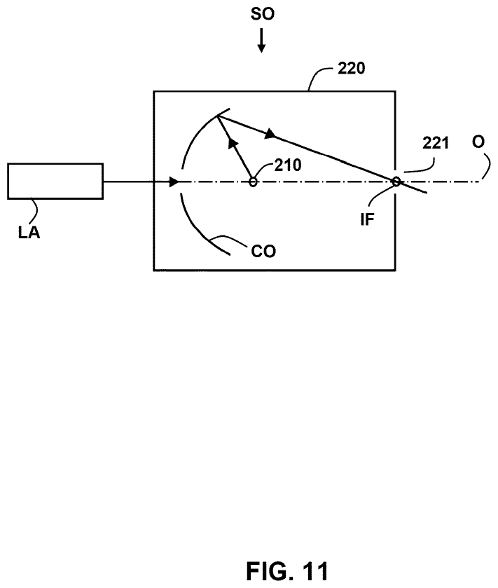

FIG. 11 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10″s of eV. The energetic radiation generated during de-excitation and recombination of these ions is emitted from the plasma, collected by a near normal incidence collector optic CO and focused onto the opening 221 in the enclosing structure 220.

Further embodiments are disclosed in the subsequent list of numbered clauses:
1. A non-transitory computer readable medium having instructions thereon, the instructions when executed by a computer causing the computer to:
   receive a representation of a contour of a substrate pattern;
   determine a curvature of the contour; and
   use a simulation model to determine an etch effect for the substrate pattern based on the curvature, wherein the simulation model comprises a correlation between etch biases and curvatures of contours.
2. The medium of clause 1, wherein the etch effect is an etch bias, and wherein the curvature is determined based on (1) a slope of the contour; and (2) a maximum or a minimum in the contour.
3. The medium of clause 1, wherein the curvature is determined based on a first derivate of the contour.
4. The medium of clause 1, wherein the curvature is determined based on a second derivative of the contour.
5. The medium of clause 1, wherein the curvature is determined based on first and second derivatives of the contour.
6. The medium of clause 5, wherein the curvature is determined by a ratio between the second derivative and the first derivative.
7. The medium of any of clauses 1-6, wherein the simulation model comprises a multi-dimensional algorithm.
8. The medium of clause 7, wherein the multi-dimensional algorithm comprises one or more non-linear, linear, or quadratic functions representative of parameters of an etching process.
9. The medium of clause 8, wherein the simulation model comprises a physical etch model or a semi-physical etch model.
10. The medium of clause 8, wherein the simulation model is an etch model.
11. The medium of clause 10, wherein the etch model comprises a multi-dimensional algorithm including a curvature term configured to correlate the curvature with the etch bias.
12. The medium of any of clauses 1-11, wherein the contour is obtained from a representation of the substrate pattern from an after development inspection for the substrate pattern.
13. The medium of any of clauses 1-11, wherein the contour is obtained from a resist model.
14. The medium of any of clauses 1-11, wherein the contour is obtained from an optical model.
15. The medium of any of clauses 1-14, wherein the etch effect comprises etch bias, and the etch bias is configured to be provided to a cost function to facilitate determination of costs associated with individual patterning process variables.
16. A method for determining an etch effect for a substrate pattern, the method comprising:
   receiving a representation of a contour of the substrate pattern;
   determining a curvature of the contour; and
   using a simulation model to determine the etch effect for the substrate pattern based on the curvature, wherein the simulation model comprises a correlation between etch biases and curvatures of contours.
17. The method of clause 16, wherein the etch effect is an etch bias, and wherein the curvature is determined based on (1) a slope of the contour; and (2) a maximum or a minimum in the contour.
18. The method of clause 16, wherein the curvature is determined based on a first derivate of the contour.
19. The method of clause 16, wherein the curvature is determined based on a second derivative of the contour.
20. The method of clause 16, wherein the curvature is determined based on first and second derivatives of the contour.
21. The method of clause 20, wherein the curvature is determined by a ratio between the second derivative and the first derivative.
22. The method of any of clauses 16-21, wherein the simulation model comprises a multi-dimensional algorithm.
23. The method of clause 22, wherein the multi-dimensional algorithm comprises one or more non-linear, linear, or quadratic functions representative of parameters of an etching process.
24. The method of clause 22, wherein the simulation model comprises a physical etch model or a semi-physical etch model.
25. The method of clause 22, wherein the simulation model is an etch model.
26. The method of clause 25, wherein the etch model comprises a multi-dimensional algorithm including a curvature term configured to correlate the curvature with the etch bias.
27. The method of any of clauses 16-26, wherein the contour is obtained from a representation of the substrate pattern from an after development inspection for the substrate pattern.
28. The method of any of clauses 16-26, wherein the contour is obtained from a resist model.
29. The method of any of clauses 16-26, wherein the contour is obtained from an optical model.
30. The method of any of clauses 16-29, wherein the etch effect is an etch bias, and the etch bias is configured to be provided to a cost function to facilitate determination of costs associated with individual patterning process variables.
31. A system for determining an etch effect for a substrate pattern, the system comprising one or more hardware processors configured by machine readable instructions to:
   receive a representation of a contour of the substrate pattern;
   determine a curvature of the contour; and
   use a simulation model to determine the etch effect for the substrate pattern based on the curvature, wherein the simulation model comprises a correlation between etch biases and curvatures of contours.
32. The system of clause 31, wherein the etch effect is an etch bias, and wherein the curvature is determined based on (1) a slope of the contour; and (2) a maximum or a minimum in the contour.
33. The system of clause 31, wherein the curvature is determined based on a first derivate of the contour.
34. The system of clause 31, wherein the curvature is determined based on a second derivative of the contour.
35. The system of clause 31, wherein the curvature is determined based on first and second derivatives of the contour.
36. The system of clause 35, wherein the curvature is determined by a ratio between the second derivative and the first derivative.
37. The system of any of clauses 31-36, wherein the simulation model comprises a multi-dimensional algorithm.
38. The system of clause 37, wherein the multi-dimensional algorithm comprises one or more non-linear, linear, or quadratic functions representative of parameters of an etching process.
39. The system of clause 38, wherein the simulation model comprises a physical etch model or a semi-physical etch model.
40. The system of clause 37, wherein the simulation model is an etch model.
41. The system of clause 40, wherein the etch model comprises a multi-dimensional algorithm including a curvature term configured to correlate the curvature with the etch bias.
42. The system of any of clauses 31-41, wherein the contour is obtained from a representation of the substrate pattern from an after development inspection for the substrate pattern.
43. The system of any of clauses 31-41, wherein the contour is obtained from a resist model.
44. The system of any of clauses 31-41, wherein the contour is obtained from an optical model.
45. The system of any of clauses 31-44, wherein the etch effect is an etch bias, and the etch bias is configured to be provided to a cost function to facilitate determination of costs associated with individual patterning process variables.
46. A non-transitory computer readable medium having instructions thereon, the instructions when executed by a computer, causing the computer to execute a simulation model for determining an etch bias for a pattern on a substrate, the etch bias determined based on a curvature of a contour in the pattern, the etch bias configured to be used to enhance an accuracy of a patterning process relative to prior patterning processes, the instructions causing operations comprising:
   receiving a representation of the pattern, wherein the representation comprises the contour in the pattern;
   determining the curvature of the contour of the pattern;
   inputting the curvature to the simulation model, wherein the simulation model comprises a correlation between etch biases and curvatures of contours; and
   outputting, based on the simulation model, the etch bias for the contour in the pattern,
wherein the etch bias from the simulation model is configured to be used in a cost function to facilitate determination of costs associated with individual patterning process variables, and wherein the costs associated with individual patterning variables are configured to be used to facilitate an optimization of the patterning process.
47. The medium of clause 46, wherein the simulation model is an etch model.
48. The medium of clauses 46 or 47, wherein the representation of the pattern comprises (1) inspection results from an after development inspection for the pattern; or (2) a model of the contour in the pattern.
49. The medium of clause 46 or 47, wherein the representation of the pattern comprises the inspection results from the after development inspection for the pattern, and wherein the inspection results from the after development inspection for the pattern are obtained from a scanning electron microscope or an optical metrology tool.
50. The medium of any of clauses 46-49, wherein the curvature is determined based on (1) a slope of the contour in the pattern; and (2) a maximum or a minimum in the contour in the pattern.
51. A non-transitory computer readable medium having instructions thereon, the instructions when executed by a computer, causing the computer to execute a simulation model for determining an etch bias for a pattern on a substrate, the etch bias determined based on a curvature of a contour in the pattern, the etch bias configured to be used to enhance an accuracy of a patterning process relative to prior patterning processes, the instructions causing operations comprising: receiving a representation of the pattern, wherein the representation comprises the contour in the pattern; determining the curvature of the contour of the pattern; inputting the curvature to the simulation model, wherein the simulation model comprises a correlation between etch biases and curvatures of contours; and outputting, based on the simulation model, the etch bias for the contour in the pattern, wherein the etch bias from the simulation model is configured to be used in a cost function to facilitate determination of costs associated with individual patterning process variables, and wherein the costs associated with individual patterning variables are configured to be used to facilitate an optimization of the patterning process.
52. The medium of clause 51, wherein the simulation model is an etch model.
53. The medium of any of the previous clauses, wherein the representation of the pattern comprises (1) inspection results from an after development inspection for the pattern; or (2) a model of the contour in the pattern.
54. The medium of any of clauses 51-53, wherein the representation of the pattern comprises the inspection results from the after development inspection for the pattern, and wherein the inspection results from the after development inspection for the pattern are obtained from a scanning electron microscope or an optical metrology tool.
55. The medium of any of clauses 51-54, wherein the curvature is determined based on (1) a slope of the contour in the pattern; and (2) a maximum or a minimum in the contour in the pattern.

The concepts disclosed herein may simulate or mathematically model any generic imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, etching simulation model and one or more of the other models described herein may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A method comprising:
receive a representation of a contour of a substrate pattern;
determine a curvature of the contour; and
use a computer simulation model to determine an etch effect for the substrate pattern based on the curvature, wherein the simulation model comprises a correlation between etch biases and curvatures of contours.

2. The method of claim 1, wherein the etch effect is an etch bias.

3. The method of claim 1, wherein the curvature is determined based on (1) a slope of the contour; and (2) a maximum or a minimum in the contour.

4. The method of claim 1, wherein the curvature is determined based on a first derivative or a second derivative of the contour.

5. The method of claim 1, wherein the curvature is determined based on first and second derivatives of the contour.

6. The method of claim 5, wherein the curvature is determined by a ratio between the second derivative and the first derivative.

7. The method of claim 1, wherein the simulation model comprises a multi-dimensional algorithm.

8. The method of claim 7, wherein the multi-dimensional algorithm comprises one or more non-linear, linear, or quadratic functions representative of parameters of an etching process.

9. The method of claim 8, wherein the simulation model comprises a physical etch model or a semi-physical etch model.

10. The method of claim 9, wherein the etch model comprises a multi-dimensional algorithm including a curvature term configured to correlate the curvatures of contours with etch biases.

11. The method of claim 1, wherein the contour is obtained from a representation of the substrate pattern from an after development inspection for the substrate pattern.

12. The method of claim 1, wherein the contour is obtained from a resist model or an optical model.

13. The method of claim 1, wherein the etch effect comprises etch bias between an after etch contour and an after development contour, and the etch bias is configured to be provided to a cost function to facilitate determination of costs associated with individual patterning process variables.

14. A non-transitory computer readable medium having instructions thereon or therein, the instructions, when executed by a computer system, configured to cause the computer system to perform at least the method of any of claim 1.

15. A system for determining an etch effect for a substrate pattern, the system comprising one or more hardware processors configured by non-transitory machine readable instructions to perform at least the method of any of claim 1.

16. A non-transitory computer readable medium having instructions thereon or therein, the instructions, when executed by a computer system, configured to cause the computer system to at least:
obtain a representation of a pattern, wherein the representation comprises a contour in the pattern;
determine a curvature of the contour of the pattern;
input the curvature to a simulation model for determining an etch bias for a pattern on a substrate;
output, based on the simulation model, the etch bias for the contour in the pattern; and
use the etch bias in a cost function to facilitate an optimization of the patterning process.

17. The medium of claim 16, wherein the simulation model is an etch model.

18. The medium of claim 16, wherein the representation of the pattern comprises (1) an inspection result from an after development inspection for the pattern; or (2) a model of the contour in the pattern.

19. The medium of claim 16, wherein the representation of the pattern comprises an inspection result from an after development inspection for the pattern, and wherein the inspection result from the after development inspection for the pattern is obtained from a scanning electron microscope or an optical metrology tool.

20. The medium of claim 16, wherein the curvature is determined based on (1) a slope of the contour in the pattern; and (2) a maximum or a minimum in the contour in the pattern.
